(19) United States
(12) Patent Application Publication
(10) Pub. No.: US 2016/0315315 A1
(43) Pub. Date: Oct. 27, 2016

(54) IMPROVED LITHIUM METAL OXIDE CATHODE MATERIALS AND METHOD TO MAKE THEM

(71) Applicant: DOW GLOBAL TECHNOLOGIES LLC, Midland, MI (US)

(72) Inventors: Michael M. Olken, Midland, MI (US); John J. Klann, Midland, MI (US)

(21) Appl. No.: 15/102,729

(22) PCT Filed: Dec. 10, 2014
(86) PCT No.: PCT/US2014/069483

§ 371 Date: Jun. 8, 2016

Related U.S. Application Data
(60) Provisional application No. 61/916,874, filed on Dec. 17, 2013.

(51) Int. Cl. H01M 4/36; H01M 4/525; H01M 4/485; H01M 4/58; C23C 16/40; H01M 10/0525; H01M 10/0585; H01M 4/131; H01M 4/1391; H01M 4/04; H01M 4/62; H01M 4/66; H01M 10/0569; H01M 10/0568; H01M 4/38; H01M 4/505

(52) U.S. Cl. CPC H01M 4/366; H01M 4/505; H01M 4/525; H01M 4/485; H01M 4/582; C23C 16/40; H01M 10/0525; H01M 10/0585; H01M 4/131; H01M 4/1391; H01M 4/0404; H01M 4/625; H01M 4/623; H01M 4/661; H01M 4/0471; H01M 4/0435; H01M 10/0569; H01M 10/0568; H01M 4/382; H01M 2004/028

(57) ABSTRACT

A coated cathode material comprises a lithium metal oxide particulate having a surface at least partially coated with a coating comprised of a complex metal oxide of aluminum and a second metal that is lanthanum, yttria or combination thereof. The coated cathode material may be made by providing a lithium metal oxide particulate which is then contacted with a precursor compound that forms a complex metal oxide upon heating. The coated lithium metal oxide is then heated to a temperature sufficient to form the complex metal oxide, wherein the complex metal oxide is amorphous and contains aluminum and a second metal that is lanthanum, yttria or combination thereof and the complex metal oxide is bonded to the lithium metal oxide.

### FIELD OF THE INVENTION

The invention relates to a method of making improved lithium metal oxide (LMO) cathode materials for use in lithium ion batteries (LIBs) and method to make them. In particular, the invention relates to a coating incorporating lanthanum and aluminum on a lithium rich metal oxide (LRMO) that improves the cycle-ability of the LIBs made from the LRMOs.

### BACKGROUND OF THE INVENTION

Lithium ion batteries have over the past couple of decades been used in portable electronic equipment and more recently in hybrid or electric vehicles. Initially, lithium ion batteries first employed lithium cobalt oxide cathodes. Due to expense, toxicological issues and limited capacity other cathode materials have been or are being developed.

One promising class of materials that has been developed is often referred to as lithium rich metal oxide or lithium rich layered oxides (LRMO). These materials generally display a layered structure with monoclinic and rhombohedral domains (two phase) in which initial high specific discharge capacities (˜270 mAh/g) have been achieved when charged to voltages of about 4.6 volts vs Li/Li⁺. Unfortunately, these materials have suffered from very short cycle life. The cycle life is generally taken as the number of cycles (charge-discharge) before reaching a specific capacity such as 80% of the initial specific capacity. Typically, the cycle life of these LIBs having LRMO cathodes has been less than 50 cycles. Each cycle for these materials is typically between the aforementioned 4.6 volts to 2 volts.

To solve the aforementioned cycle life problem among others, dopant metals other than those typically used to make the LRMOs and coating have been described such as in US Pat. Publ. Nos. 2013/149609; 2012/0263998; 2011/0081578; and 2007/0281212 and U.S. Pat. No. 7,435,402. Unfortunately, the improvements generally have been able to merely improve the cycle life on the order of a few tens or twenties, but at significant reduction of other properties such as initial specific discharge capacity.

Accordingly, it would be desirable to provide an improved LRMO and method to make the LRMO that improves LIBs made therefrom such as improving the cycle life of such batteries, without substantially reducing other desirable properties of these LIBs. In particular, it would be desirable to provide a method of coating an LRMO so that the LIB that is formed has improved cycle life and other desirable properties.

### SUMMARY OF THE INVENTION

We have discovered a coating that is useful for improving the performance of LMOs and in particular LRMOs. The coating surprisingly enhances the cycle life of LIBs made from LRMOs compared to prior coatings. Illustratively, a cycle life of over 250 cycles has been possible.

A first aspect of the invention is a composition useful as a cathode material comprising a lithium metal oxide particulate having a surface at least partially coated with a coating comprised of a complex metal oxide of aluminum and a second metal that is lanthanum, yttria or combination thereof.

A second aspect of the invention is a method of making a lithium metal oxide coated with a complex metal oxide comprising

(i) providing a lithium metal oxide particulate,

(ii) contacting the lithium metal oxide with a precursor compound that forms a complex metal oxide upon heating, and

(iii) heating to a temperature sufficient to form the complex metal oxide, wherein the complex metal oxide is amorphous and contains aluminum and a second metal that is lanthanum, yttria or combination thereof and the complex metal oxide is bonded to the lithium metal oxide.

### BRIEF DESCRIPTION OF THE DRAWINGS

FIG. 1 is a graph of the capacity retention of a battery made with cathode material made with the composition of the invention versus batteries made with a cathode using cathode materials not of this invention.

FIG. 2 is a graph of the capacity retention of batteries made with cathode material of the invention in which the heat treatment temperature to make the cathode material was varied versus batteries made with a cathode using cathode materials not of this invention.

### DETAILED DESCRIPTION OF THE INVENTION

The LMO that is coated to form the coated LMO of this invention may be any suitable lithium metal oxides (LMOs) useful to form a lithium ion battery (LIB). The lithium metal oxide is preferably a lithium rich metal oxide (LRMO). The LMO may be any suitable one such as those known in the art. Exemplary LRMOs include those described in U.S. Pat. Nos. 5,993,998; 6,677,082; 6,680,143; 7,205,072; and 7,435,402, Japanese Unexamined Pat. No. 11307094A, EP Pat. Appl. No. 1193782; Chem. Mater. 23 (2011) 3614-3621; J. Electrochem. Soc., 145:12, December 1998 (4160-4168). The lithium metal oxide is preferably a lithium rich metal oxide (LRMO). Desirably, the LRMO is one wherein the metal is comprised of Mn or Co. Preferably the metal is comprised of Mn and at least one other metal that is a transition metal, rare earth metal or combination thereof or is comprised of LiₓCoO₂ where x is greater than 1 and less than 2. More preferably, the metal is comprised of Mn, Ni and Co.

Illustratively, the lithium rich layered metal oxide is represented by a formula:

LiₓM_{y}O₂

Where 1<x<2, y is 1 and the metal may be any metal that has an oxidation state from 2 to 4. Preferably, M is a combination of metals, wherein one of the metals is Ni and it is present in a sufficient amount such that it is present in an oxidation state of at least +2. In a preferred embodiment, M is Ni, Mn and Co such that the composition in Ni_{1-a-b}MnₐCo_{b} can be described as 0.2≦a≦0.9 and 0≦b≦0.8.

It is understood that the LRMOs may also contain small amounts of anionic dopants that improve one or more properties, with an example being fluorine. Exemplary LRMOs include those described by U.S. Pat. Nos. 7,205,072 and 8,187,752.

The LRMOs typically display a specific capacity, after being initially charged to 4.6 volts by a typical formation method, of at least about 250 mAh/g when discharged at a C rate of 0.05 between 2 and 4.6 volts. A C rate of 1 means charging or discharging in 1 hour between the aforementioned voltages and a C/10 is a rate where the charging or discharging equals 10 hours and a 10 C rate is equal to 6 minutes.

The LMO generally has a median (D50) primary particle size of 0.1 micrometer to 5 micrometers. Primary particle means the smallest distinct division of a given phase as is readily determined by microscopy and is analogous, for example, to a grain in a fully dense ceramic. The D50 primary particle size is desirably at least 0.2, 0.4 or 0.5 to 4, 3, or 2 micrometers. The particle size distribution is given by D10 and D90 particles sizes. D10 is the size where 10% of the particles are smaller and D90 is the particle size where 90% of the particles are smaller in a given distribution by number. The D10 typically is 0.1, 0.2, or 0.3 micrometer. The D90 is typically 8, 5, or 4 micrometers.

The lithium metal oxide has a median (D50) secondary particle size by number that is useful to achieve a suitable pour density and tap density to achieve suitable densities on a metal foil when making the cathode of this invention. Secondary particle size means a cluster of primary particles bonded together either by hard or soft bonding where hard bonding is by chemical bonds such as covalent or ionic bonding and soft bonding is by hydrogen, van der Waals or mechanical interlocking. The primary particles making up the lithium metal oxide typically are bonded at least in part by hard bonding. Generally, the D50 secondary particle size by number is 2 to 30 micrometers. Desirably, the secondary particle size D50 is 3, 4, or 5 to 25, 20 or 15 micrometers. The lithium metal oxide secondary particles typically have a D10 that is 3, 4, or 5 micrometer and a D90 that is 12, 16, or 20 micrometers.

The LMO generally has a specific surface area that is 0.1 m²/g to 500 m²/g. Typically, the specific surface area is 0.5, 1, 2 or 5 m²/g to 250, 100, 50, or 20 m²/g. Surface area of the particles maybe measured by multi-point Brunauer-Emmett-Teller (BET) surface area measurement based on N₂ gas adsorption on sample surfaces.

The LMO is coated on at least a portion of its surface with the coating of this invention. “Portion” means any amount of coating that is sufficient to improve the properties, in particular, cycle-ability, of the LMO when coated. Because the LMO is commonly in the form of secondary particles made up of primary particles this typically means at least 5% of the surface of the LMO is coated with the invention's coating. Desirably, at least 20, 30, 40, 60, 80, 90% to 100% of the surface of the LMO is coated with the coating. Because the LMO is commonly in the form of secondary particles made up of primary particles, a preferred embodiment is where the primary particles residing at the surface of the secondary particles (“surface primary particles) have a greater portion of their surface coated than those primary particles (“core primary particles”) residing entirely within the secondary particle.

Likewise, the thickness may be any suitable thickness, but generally is practically as thin as possible, such that the volume of the coating compared to the volume of the LMO particles is at most about 20% of the coated LMO. Preferably, the volume of the coating is from about 0.1%, 0.2%, 0.5%, 1% or 2% to about 15%, 10% or 5% of the total volume of the coated LMO. The thickness of the coating generally is on the order of 0.5 to 2.5 nanometers.

The complex metal oxide is an oxide comprised of aluminum and a second metal that is lanthanum, yttria or combination thereof. The complex metal oxide generally has a formula of AlMO₃ wherein the ratio of the Al/M may be any useful ratio such as 0.1, 0.5, 0.75 to 1.5, 2, or 10. Desirably the ratio is essentially 1 meaning the ratio within reasonable practical limits is from 0.95 to 1.05.

In a preferred embodiment, the coating is amorphous. Amorphous means that there is no molecular structure that is detectable using typical analytical techniques. That is, there may be some very small ordered structure, but due to the size of such order, the techniques to measure such order, for example, fails to detect or is not substantially different than an amorphous material. For example, the ordered domains may be of such a small size that X-ray diffraction or electron diffraction results in such diffuse scattering that if such domains were present they would be of a size of at most about 10 nanometers or less.

In another embodiment, the coating is at least partially crystalline and the crystalline structure is one having the perovskite crystalline structure. The amount of crystalline structure may be any amount such as 5% to 100% of the volume of the coating.

To form the composition the LMO described is provided and contacted with a compound that is or forms the coating comprised of the complex metal oxide.

In one embodiment the method comprises dissolving the precursor compound metal in a liquid. The liquid may be any liquid that dissolves a compound containing yttria, lanthanum or oxygen. Typically, the liquid is a polar solvent that is capable of solvating metal salts. Exemplary solvents include alcohols, ethers, esters, organic and inorganic acids, ketones, aromatics, water and mixtures thereof. It is desirable for the polar solvent to be water, tetrahydrofuran, isopropanol, ethanol, tartaric acid, acetic acid, acetone, methanol, dimethylsulfoxide, n-methyl-pyrolidone, acetonitrile, or a combination thereof. Desirably, the solvent is water, which may be neutral, acidic or basic depending on the particular compounds to be dissolved.

Even though the aluminum, yttria and/or lanthanum may be dissolved directly for example in a sufficiently acidic aqueous solution, it is preferable to dissolve a compound such as an ionic compound (e.g., salt). Exemplary compounds of the aforementioned metals include a nitrate, sulfate, hydroxide, carboxylate, carbonate, chloride, fluoride, iodide alkoxide (e.g., isopropoxide or ethoxide), acetylacetonate, acetate, oxalate, or mixture thereof. Preferably, the compound is a nitrate, hydroxide, carboxylate, oxalate, carbonate or mixture thereof. Most preferably the compound is a nitrate. It is understood that the compound, may be mixed metal compounds or one or more singular metal compounds that are dissolved in the liquid when a combination of Y or La with the Al is desired. Preferably, the compound is aluminum nitrate hydrate and yttrium nitrate hydrate, lanthanum nitrate hydrate or combination thereof.

Upon contacting the LMO with the liquid containing the dissolved compounds, the compounds may be deposited on the surface of the LMO by any suitable methods. This may be accomplished by merely preferentially removing the liquid (i.e., drying) resulting in precipitation of the compounds on the LMO particulates. The precipitation preferably is accomplished by a change in condition to the dissolved compounds in the liquid, such as change in temperature, pH, addition of non-solvent, or combination thereof, which would then be followed by removal of the liquid. The contacting of the liquid may also be by an incipient wetness method such as described in co-pending U.S. Provisional Application No. 61/867256.

In a preferred embodiment, the precipitation is carried out by an increase in temperature and change in pH of an aqueous concentrated solution of dissolved precursor salts having a desired molar ratio (e.g., 1:1 molar lanthanum to Al, Y or combination thereof). Concentrated means that the lo salts are present in sufficient concentration to practically and effectively precipitate the salt from solution without selectively removing the liquid, for example, by drying. Illustratively, when the salts are nitrates this means the concentration typically is at least 1 Molar to the super saturation concentration of the salts in the particular liquid (e.g., water).

After the concentrated solution is made, the LMO solid is added to the solution and the resultant slurry is agitated to ensure that the LMO is fully wetted and suspended. A quantity of a base such as ammonium hydroxide is added slowly to the slurry which is then heated to 50° C. for a sufficient time (e.g., 0.5, 1, 2 to 10, 8, 6 or 5 hours). During the heating, a complex metal hydroxide, oxyhydroxide, or oxide is deposited onto the surface of the LMO solid. After the deposition is complete, the resultant coated solid is collected by filtration, washed with water, and then dried and calcined as described below.

In another embodiment, the compound may be present as a solid in colloid dispersion so long as the particulate size of the colloid suspended in the liquid is of small enough size to form a coating (e.g., at least about order of magnitude smaller than the primary particle size of the LMO). Typically, the colloid particles when using such a method have an average particle size of at most about 100 nm to about 1 nm. Desirably the average particle size of the colloid is at most 75, 50, or 25 nm.

The dissolving may be aided by the application of heating and stirring, but is generally not necessary so long as the compound is dissolved in the liquid in the desired amount at ambient conditions. The amount needed in the liquid is readily determinable from the amount desired and lo the amount of solution necessary to make the coating.

Once the solution has been contacted with the LMO, the liquid of the solution is removed leaving the compound or compounds on the surface of the LMO. The removing of the liquid may be accomplished by any suitable method, such as evaporative drying without assistance or with assistance such as heating, freeze drying, vacuum drying or the like. The heating may be done by any suitable method such as microwave, induction, convection, resistance, radiation heating or combination thereof. The drying and subsequent heating to form the LMO coated with the complex metal oxide may be done in one process step or in separate process steps. The temperature of the drying when employing heating may be any useful temperature, but is typically from about 50° C. to about 150° C. The time likewise may be any suitable time that is useful, for example, several minutes to hours.

The LMO having the compound deposited thereon is heated to a temperature sufficient to form the desired LMO coated with the complex metal oxide.

The temperature of heating the LMO having the deposited compound to form the LMO coated with the complex metal oxide is a temperature that is sufficient to adequately bond the complex metal oxide to the surface of the LMO such that it can withstand any subsequent processing to form a battery. It has surprisingly been found that the temperature should not be too high to realize the most beneficial performance, which generally is indicated by the coating being amorphous. Desirably, the temperature is from 300° C., 325° C., 375° C., to 500° C., 450° C. or 425° C. The temperature may be higher than 500° C., such as 1000° C. or even 800° C., but this is less preferred. The heating may also contain one or more holds at differing temperature until the final temperature desired is reached.

The atmosphere may be oxidative, inert, or vacuum or combination thereof during the heating. Preferably the atmosphere is oxidative, with dry or atmospheric air being suitable.

The time at the heating temperature may be any useful time, but, is desirably as short a time possible that still achieves the desired LMO coated with the complex metal oxide. The time, for example, may be seconds to several days. Typically the time is several minutes to 3 to 4 hours, which is also applicable to any intermediate temperature hold.

The coated LMO and particular those LMO's having excess Li (referred to as lithium rich metal oxides or LRMOs herein) of this invention has been surprisingly found to give improved cycle life without substantial decreases in other useful properties of the LRMOs. For example, an LIB having an LRMO made by this invention's method may have a cycle life of 50% or greater compared to an LRMO not having the complex metal oxide. The cycle life may be more than 200, 300, 400 or even 500 cycles.

Lithium ion batteries (LIBs) comprised of a cathode comprised of the invention's composition may have any suitable design. Such a battery typically comprises, in addition to the cathode, an anode, a porous separator disposed between the anode and cathode, and an electrolyte solution in contact with the anode and cathode. The electrolyte solution comprises a solvent and a lithium salt.

Suitable anode materials include, for example, carbonaceous materials such as natural or artificial graphite, carbonized pitch, carbon fibers, graphitized mesophase microspheres, furnace black, acetylene black, and various other graphitized materials. Suitable carbonaceous anodes and methods for making them are described, for example, in U.S. Pat. No. 7,169,511. Other suitable anode materials include lithium metal, lithium alloys, other lithium compounds such as lithium titanate and metal oxides such as TiO₂, SnO₂ and SiO₂, as well as materials such as Si, Sn, or Sb. The anode may be made using one or more suitable anode materials.

The separator is generally a non-conductive material. It should not be reactive with or soluble in the electrolyte solution or any of the components of the electrolyte solution under operating conditions but must allow lithium ionic transport between the anode and cathode. Polymeric separators are generally suitable. Examples of suitable polymers for forming the separator include polyethylene, polypropylene, polybutene-1, poly-3-methyl-pentene, ethylene-propylene copolymers, polytetrafluoro-ethylene, polystyrene, polymethylmethacrylate, polydimethylsiloxane, polyethersulfones and the like.

The battery electrolyte solution has a lithium salt concentration of at least 0.1 moles/liter (0.1 M), preferably at least 0.5 moles/liter (0.5 M), more preferably at least 0.75 moles/liter (0.75 M), preferably up to 3 moles/liter (3.0 M), and more preferably up to 1.5 moles/liter (1.5 M). The lithium salt may be any that is suitable for battery use, including lithium salts such as LiAsF₆, LiPF₆, LiPF₄(C₂O₄), LiPF₂ (C₂O₄)₂, LiBF₄, LiB (C₂O₄)₂, LiBF₂ (C₂O₄) , LiClO₄, LiBrO₄, LiIO₄, LiB(C₆H₅)₄, LiCH₃SO₃, LiN(SO₂C₂F₅)₂, and LiCF₃SO₃. The solvent in the battery electrolyte solution may be or include, for example, a cyclic alkylene carbonate like ethylene carbonate; a dialkyl carbonate such as diethyl carbonate, dimethyl carbonate or methylethyl carbonate, various alkyl ethers; various cyclic esters; various mononitriles; dinitriles such as glutaronitrile; symmetric or asymmetric sulfones, as well as derivatives thereof; various sulfolanes, various organic esters and ether esters having up to 12 carbon atoms, and the like.

### EXAMPLES

Each of the Examples and Comparative Examples within a specific Table used the same lithium rich metal oxide material. Three different LMO materials were utilized with each possessing the same overall chemical formula Li_{1.2}(Ni_{0.17}Mn_{0.56}Co_{0.07})O₂. These materials were all prepared using known coprecipitation methods employing carbonate precursors. LMO 1 utilized a precursor prepared in a 50 liter pilot scale reactor while both LMO 2 and LMO 3 were prepared using carbonate precursors prepared in a lab scale 4 liter reactor with the same composition as LMO 1. The resultant transition metal carbonates were mixed with the desired quantity of lithium carbonate and calcined in air at 850° C. to produce LMO. The characteristics of the LMOs are shown in Table 1.

Coin cells were manufactured in the same way using the coated LRMO produced in each Example and Comparative Example as follows.

The LRMO or coated LRMO of each Example and Comparative Example was mixed with SUPER P™ carbon black (Timcal Americas Inc., Westlake, Ohio), VGCF™ vapor grown carbon fiber (Showa Denko K.K., Japan) and polyvinylidene fluoride (PVdF) (Arkema Inc., King of Prussia, Pa.) binder in a weight ratio of LRMO:SuperP:VGCF:PVdF of 90:2.5:2.5:5. A slurry was prepared by suspending the cathode material, conducting material, and binder in solvent N-Methyl-2-pyrrolidone (NMP) followed by homogenization in a vacuum speed mixer (Thinky USA, Laguna Hills, Calif.). The NMP to solids ratio was approximately 1.6:1 before defoaming under mild vacuum. The slurry was coated on to battery grade aluminum foil using a doctor blade to an approximate thickness of 30 micrometers and dried for thirty minutes at 130° C. in a dry convection oven. The aluminum foil was 15 micrometers thick. 2025 type coin cells were made in a dry environment (dew point less than or equal to −40° C.)

The electrodes were pressed on a roller press to approximately 17 micrometers resulting in an active material density of about 2.7 to about 3.0 g/cc. The cells had a measured loading level of about 5 mg/cm². The electrolyte was ethylene carbonate/diethyl carbonate (EC:DEC, 1:9 by volume) with 1.2 M LiPF₆. The anode was 200 micrometer thick high purity lithium foil available from Chemetall Foote Corporation, New Providence, N.J. The separator was a commercially available coated separator.

The cells were cycled on a MACCOR Series 4000 battery testing station (MACCOR, Tulsa, Okla.). Cells were activated by charging at C/20 to 4.6 V followed by a 30 minute constant voltage hold. Cycling was performed between 4.6 volts and 2 volts using C/3 charge and 1C discharge rates. At a 25 cycle interval, a C/10 discharge was performed. Prior to cycling in the aforementioned manner, the cells were first cycled to determine the initial capacity of the battery at a C rate of 0.05 and then the capacity was also determined, in order thereafter at C rates of 0.1, 0.33, 1, 3, 5.

### EXAMPLE 1

In a beaker, 1.12 g of aluminum nitrate nonahydrate (Al(NO₃)₃.9H₂O) and 1.30 g lanthanum nitrate hexahydrate (La(NO₃)₃.6H₂O) were dissolved in 4 ml of water and set aside. 18 ml of water was added to a 250 ml three-neck round-bottom flask equipped with a condenser and overhead stirring. Stirring was initiated at 200 RPM and 25.0 g LMO 1 was added to the flask, resulting in a black slurry. The pH of the slurry was then measured, pH=10.60. The aluminum nitrate and lanthanum nitrate solution were then quickly added to the slurry. The pH was then measured, pH=4.95. A pipette was then used to add 9 ml of 2M ammonium hydroxide (NH₄OH) solution to the slurry at a rate of 2 ml/min. After the addition, the pH of the slurry was measured, pH=9.82. The open neck of the flask was then closed with a septum. A thermometer was then inserted through the septum into the slurry.

With continued stirring, a heating mantle was used to heat the slurry to 50° C. The slurry was stirred at 50° C. for 4 hours before being allowed to cool back to room temperature. Once cool, the pH of the slurry was measured, pH=9.86.

The slurry was vacuum filtered using a Buchner funnel, fine filter paper and a vacuum flask attached to a water aspirator. The black solids were washed with 60 ml of water while on the filter. The liquid was discarded and the black solids were allowed to dry on the filter for 2 hours in a fume hood. The solids and filter paper were then transferred to a glass dish and placed in a 100° C. oven overnight to dry.

The dried black powder was then recovered and placed in an alumina crucible and calcined in an air-purged furnace. The furnace program consisted of a ramp rate of 100° C./hour to 400° C., followed by a 4 hour hold at 400° C., after which the furnace shut off and was allowed to cool to room temperature. Once cool, the black solids were collected and weighed. The solids were sieved to under 45 microns before analytical characterization and being made into batteries as described above and the electrochemical performance assessed.

The resultant coated LMO 1 powder of this Example 1 had a chemical composition that was Li_{1.48} [Ni_{0.21} Mn_{0.70} Co_{0.09}]O_{2.25} which is also shown in Table 1. The amount of coating was 2.4 wt % of lanthanum aluminum oxide having the composition in Table 2. The composition was determined using Inductively coupled plasma mass spectroscopy analysis (ICP).

An X-ray diffraction (XRD) pattern of the coated LMO 1 powder of this Example was identical to that of the original uncoated LMO 1 and did not any display any new peaks which would be indicative of additional crystalline phases such as LaAlO₃, Al₂O₃, or La₂O₃.

Transmission electron microscopy (TEM) revealed an amorphous coating containing lanthanum aluminum oxide of uneven thickness on the primary particles. The average film thickness was 0.5 to 2.5 nanometers along with some portions of the particle surface appearing to not possess any coating. The electrochemical performance of a cell made from this Example's cathode material is shown in Table 2.

### COMPARATIVE EXAMPLE 1

Comparative Example 1 employed LMO 1 without any coating or further treatments when making the cell for testing. The electrochemical performance of the cell made from LMO 1 (i.e., this Comp. Ex.) is shown in Table 2.

### EXAMPLES 2 AND 3 AND COMP. EXAMPLES 2 TO 6

In these Examples the same procedure was used to make coated LMO 1 as in Example 1 except that the amount of the compounds used were changed to realize the coating compositions shown in Table 2. When the composition employed yttrium, the compound dissolved was yttrium nitrate hydrate.

In Example 2, the preparation was identical to Example 1 except that only half the amount of lanthanum nitrate hydrate was utilized to give a final loading of 1.6 wt % lanthanum aluminum oxide

In Example 3, yttrium nitrate hydrate was employed. In a small beaker, 0.91 g Al(NO₃)₃-9H₂O and 0.93 g Y(NO₃)₃-6H₂O were dissolved in 4 ml of deionized water and set aside. 14 ml of deionized water was added to a 250 ml three-neck round-bottom flask equipped with a condenser and overhead stirring. Stirring was initiated at 200 RPM and 20.0 g LMO 1 was added, resulting in a black slurry. The pH of the slurry was then measured, pH=11.30. The aluminum nitrate and yttrium nitrate solution were then quickly added to the slurry. The pH was then measured, pH=4.81. A pipette was then used to add 7.3 ml of 2M NH₄OH solution to the slurry at a rate of 2 ml/min. After the addition, the pH of the slurry was measured, pH=9.82. The open neck of the flask was then closed with a septum. A thermometer was then inserted through the septum into the slurry.

With continued stirring, a heating mantle was used to heat the slurry to 50° C. The slurry was stirred at 50° C. for 4 hours before being allowed to cool back to room temperature. Once cool, the pH of the slurry was measured, pH=9.85.

The slurry was vacuum filtered using a Buchner funnel, fine filter paper and a vacuum flask attached to a water aspirator. The black solids were washed with 50 ml of deionized water while on the filter. The filtered liquid was colorless. The liquid was discarded and the black solids were allowed to dry on the filter for 2 hours. The solids and filter paper were then transferred to a glass dish and placed in a 100° C. oven overnight to dry.

The dried black solids were then recovered and placed in an alumina crucible and calcined in an air-purged furnace. The furnace program consisted of a ramp rate of 100° C./hour to 400° C., followed by a 4 hour hold at 400° C., after which the furnace was shut off and was allowed to cool to room temperature. Once cool, the black solids were collected and weighed. The solids were sieved to under 45 micrometers before being submitted for testing.

### COMPARATIVE EXAMPLE 7

In a small beaker, 1.11 g of Al(NO₃)₃-9H₂0 was dissolved in 3 ml of deionized water and set aside. In another small beaker, 0.66 g of NH₄F was dissolved in 3 ml of deionized water and set aside. 25 ml of deionized water was added to a 250 ml three-necked round bottom flask equipped with a condenser and overhead stirring. Stirring was initiated at 200 RPM and 25.0 g of LMO 1 was added, resulting in a black slurry. The pH of the slurry was measured, pH=11.52. The aluminum nitrate solution was then quickly added to the slurry. The pH of the slurry was measured, pH=7.87. A pipette was then used to add the NH4F solution to the slurry at a rate of 2 ml/minute. After the addition, the pH of the slurry was measured, pH=9.40. The open neck of the flask was sealed with septum. A thermometer was then inserted through the septum into the slurry.

With continued stirring, a heating mantle was used to heat the slurry to 80° C. The slurry was stirred at 80° C. for 4 hours before being allowed to cool back to room temperature. Once cool, the pH of the slurry was measured, pH=10.21.

The slurry was then vacuum filtered using a Buchner funnel, fine filter paper, and a vacuum flask attached to a water aspirator. The black solids were washed with 50 ml of deionized water while on the filter. The filtered liquid was colorless. The liquid was discarded and the black solids were allowed to dry on the filter for 2 hours. The solids were then placed in a 100° C. oven overnight to dry.

The dried black solids were then transferred to an alumina crucible and calcined in an air-purged furnace to 400° C. The furnace program consisted of a ramp rate of 100° C./hour to 400° C., followed by a 4 hour hold at 400° C., after which the furnace shut off and was allowed to cool to room temperature. Once cool, the black solids were collected and weighed. The solids were sieved to under 45 micrometers before being submitted for testing.

### EXAMPLES 4 TO 8

Examples 4 to 8 were made the same way as described in Example 1, except that LMO 2 was used and the calcination temperature that was used to finally form the coating was as shown in Table 3.

In making Examples 4 to 8, a 100 g portion of LMO 2 was coated with 2.6 wt % lanthanum aluminum oxide as described in Example 1 and dried in a 100° C. oven overnight. The resultant solid was divided into five equal portions each of which was then calcined to a different final temperature for four hours. The temperatures utilized were 150, 400, 550, 700, and 850° C. after which the furnace shut off and was allowed to cool to room temperature. Once cool, the black solids were collected and weighed. The solids were sieved to under 45 microns before being submitted for electrochemical testing and analytical characterization.

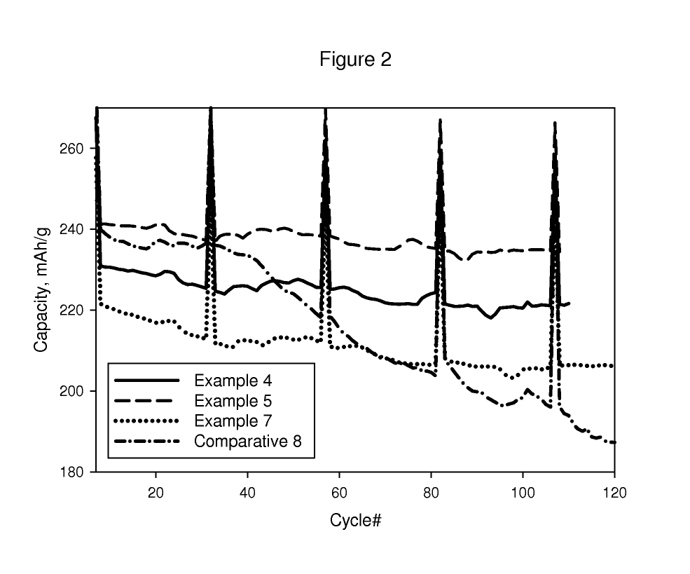

The best capacity vs cycling performance was realized with the 400° C. treatment as shown in FIG. 2.

### EXAMPLE 9

Example 9 used a lower amount of Lanthanum aluminum oxide coating, 1.5 wt % vs 2.6 wt % and 400° C. calcination. The procedure was the same as Example 1 except that less lanthanum nitrate hydrate and aluminum nitrate hydrate were utilized to give a final coating of Lanthanum aluminum oxide of 1.5 wt %

### EXAMPLES 10 AND 11

Examples 10 and 11 were made using incipient wetness as a means to add the metal precursors to the LMO material instead of the previously described deposition-precipitation method.

In Example 10, a 2.6 wt % lanthanum aluminum oxide coating was deposited as follows. The incipient wetness volume of the LMO 2 was determined by weighing out 1.0 g into a small beaker and adding water drop-wise until the powder was thoroughly moistened and tacky. The incipient wetness volume was determined to be 0.37 ml/g.

10 g of LMO 2 was added to small beaker. In a small vial, 0.45 g of aluminum nitrate nonahydrate and 0.52 g lanthanum nitrate hexahydrate was dissolved in 3.7 ml of deionized water. This solution was then added drop-wise to the Li-rich material in the beaker. After each few drops, the mixture was stirred with a metal spatula and any clumps were broken up. After all the solution was added and the material was well mixed, the result was a slightly damp, tacky solid. The beaker was then placed in a 100° C. oven overnight to dry the material.

Once dry, 3.6 ml of 2M ammonium hydroxide was diluted to 3.7 ml using deionized water. This solution was then added drop-wise to the Li-rich material in the beaker. After each few drops, the mixture was stirred with a metal spatula and any clumps were broken up. After all the solution was added and the material was well mixed, the result was a slightly damp, tacky solid. The beaker was then placed in a 100° C. oven overnight to dry the material.

Once dry, the black solids were then transferred to an alumina crucible and calcined in an air-purged furnace to 400° C. The furnace program consisted of a ramp rate of 100° C./hour to 400° C., followed by a 4 hour hold at 400° C., after which the furnace shut off and was allowed to cool to room temperature. Once cool, the black solids were collected and sieved to 45 micrometers before being submitted for testing.

### EXAMPLE 11

This sample was prepared in a similar fashion to example 10 except that the ammonium hydroxide was impregnated before the aluminum and lanthanum nitrate solution. All the added quantities, and drying and calcination procedures utilized were the same as in Example 10.

### COMPARATIVE EXAMPLES 8 AND 9

Comparative Example 8 employed LMO 2 without any coating or further treatments when making the cell for testing. Comparative 9 was the same as Comparative Example 7 except that LMO 2 was used.

### EXAMPLES 12 TO 14

Example 12 was prepared as described in Example 1 except that LMO 3 was used and the composition and amount of the coating was as shown in Table 4. Examples 13 and 14 utilized twice-coated LMO 3 involving both lanthanum aluminum oxide and aluminum fluoride each added in separate depositions. The same compounds were used for AlF₃ as was used in Comparative Example 7.

Example 13 was made as follows. In a small beaker, 0.46 g of Al(NO₃)₃-9H₂O and 0.53 g of La(NO₃)₃-6H₂O were dissolved in 2 ml of deionized water and set aside. 16 ml of deionized water was added to a 250 ml three-neck round-bottom flask equipped with a condenser and overhead stirring. Stirring was initiated at 200 RPM and 20.0 g of LMO 3 was added, resulting in a black slurry. The pH of the slurry was then measured, pH=11.08. The aluminum nitrate and lanthanum nitrate solution was then quickly added to the slurry. The pH was then measured, pH=6.54. A pipette was then used to add 7.3 ml of 1M NH₄OH solution to the slurry at a rate of 2 ml/min. After the addition, the pH of the slurry was pH=10.15. The open neck of the flask was then closed with a septum. A thermometer was then inserted through the septum into the slurry.

With continued stirring, a heating mantle was used to heat the slurry to 50° C. The slurry was stirred at 50° C. for 4 hours before being allowed to cool back to room temperature. Once cool, the pH of the slurry was measured, pH=10.38.

The slurry was vacuum filtered using a Buchner funnel, fine filter paper and a vacuum flask attached to a water aspirator. The black solids were washed with 50 ml of deionized water while on the filter. The filtered liquid was colorless. The liquid was discarded and the black solids were allowed to dry on the filter for 2 hours. The solids and filter paper were then transferred to a glass dish and placed in a 100° C. oven overnight to dry.

The dried black solids were then recovered and placed in an alumina crucible and calcined in an air-purged furnace. The furnace program consisted of a ramp rate of 100° C./hour to 400° C., followed by a 4 hour hold at 400° C., after which the furnace shut off and was allowed to cool to room temperature. Once cool, the black solids were collected.

The above lanthanum aluminum oxide coated LMO 3 was then additionally coated with aluminum fluoride as follows. In a small beaker, 0.89 g of Al(NO₃)₃-9H₂O was dissolved in 2 ml of deionized water and set aside. In another small beaker, 0.26 g NH₄F was dissolved in 2 ml of deionized water and set aside. 21 ml of deionized water was added to a 250 ml three-necked round bottom flask equipped with a condenser and overhead stirring. Stirring was initiated at 200 RPM and the lanthanum aluminum oxide coated LMO 3 was added, resulting in a black slurry. The pH of the slurry was measured, pH=10.03. The aluminum nitrate solution was then quickly added to the slurry. The pH of the slurry was measured, pH=4.27. A pipette was then used to add the NH₄F solution to the slurry at a rate of 2 ml/minute. After the addition, the pH of the slurry was measured, pH=8.87. The open neck of the flask was sealed with septum. A thermometer was then inserted through the septum into the slurry.

With continued stirring, a heating mantle was used to heat the slurry to 80° C. The slurry was stirred at 80° C. for 4 hours before being allowed to cool back to room temperature. Once cool, the pH of the slurry was measured, pH=10.20.

The slurry was then vacuum filtered using a Buchner funnel, fine filter paper, and a vacuum flask attached to a water aspirator. The black solids were washed with 50 ml of deionized water while on the filter. The filtered liquid was colorless. The liquid was discarded and the black solids were allowed to dry on the filter for 2 hours. The solids were then placed in a 100° C. oven overnight to dry.

The dried black solids were then transferred to an alumina crucible and calcined in an air-purged furnace to 400° C. The furnace program consisted of a ramp rate of 100° C./hour to 400° C., followed by a 4 hour hold at 400° C., after which the furnace shut off and was allowed to cool to room temperature. Once cool, the black solids were collected and weighed. The solids were sieved to under 45 microns before being submitted for testing.

Example 14 was performed identically to Example 13 except that twice the quantities of lanthanum nitrate hydrate and aluminum nitrate hydrate were utilized during the first coating step to form the lanthanum aluminum oxide coating.

### COMPARATIVE EXAMPLES 10 AND 11

Comparative Example 10 employed LMO 3 without any coating or further treatments when making the cell for testing. Comparative 11 was the same as Comparative Example 7 except that LMO 3 was used.

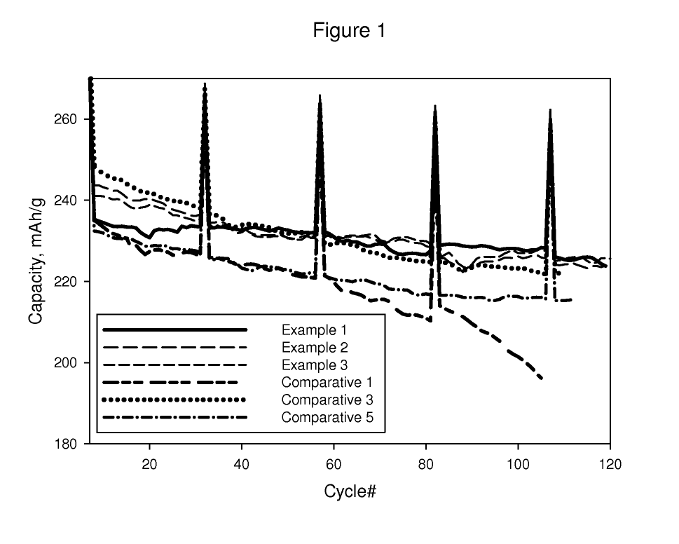

From the Table 2 and FIG. 1, LMO coated with coatings of this invention display surprisingly improved capacity retention with very little initial capacity loss compared to LMO without any coating (see Examples 1 to 3 v. Comp. Ex. 1). In addition, the coatings of the invention display improved cycle life compared to coating of the individual oxides (e.g., Al₂O₃ and La₂O₃) based upon the volume of the coating based upon the crystalline densities of each. For example, Comparative Example 3 has similar initial capacities to Examples 1 to 3, but from the FIG. 1, it is readily apparent that the capacity retention has significantly steeper decay and is expected to have a much shorter cycle life (cycles where 80% capacity is reached). Even though La₂O₃ appears to have similar capacity retention when larger amounts are used (Comp. Ex. 6), this Comp. Ex. has degraded rate capability as shown by the 1C data in Table 2, which is further accentuated even at higher C rates. In summary, the use of the particular complex oxides has been found to deliver excellent capacity retention and retention at high discharge rates.

From Table 3 and FIG. 2, it is readily apparent that the temperature used to form the coating of the invention is important to realize the best performance in a battery. Surprisingly, the temperature is substantially less than temperatures used to calcine these type of materials with coatings calcined at 400° C. displaying the best performance.

From Table 4, Examples 13 and 14 show that the coatings of the present invention may also be combined with other known coatings to form useful cathode active materials for batteries.

TABLE 1

| | LMO 1 | LMO 2 | LMO 3 |
|---|---|---|---|
| Characteristic | (Ex. 1-3 & Comp. 1-7) | (Ex. 4-11 & Comp. 8 & 9) | (Ex. 12-14 & Comp. 10 & 11 |
| Chemistry | Li_{1.48(Ni}_{0.21}Mn_{0.70}Co_{0.09})O_{2.25} | Li_{1.45(Ni}_{0.21}Mn_{0.70}Co_{0.09})O_{2.25} | Li_{1.47(Ni}_{0.21}Mn_{0.70}Co_{0.09})O_{2.25} |
| Surface Area | 5.5 | 5.6 | 6.6 |
| (m²/g) | | | |

TABLE 2

| | | | | | C/10 | | | |
|---|---|---|---|---|---|---|---|---|
| | | | 7^{th} cycle | 107^{th} cycle | Capacity | 8^{th} cycle | 106^{th} cycle | 1 C |
| | | | C/10 | C/10 | Retention | 1 C | 1 C | Capacity |
| | Coating | Coating | Capacity | Capacity | (7-107 | Capacity | Capacity | Retention |
| Example | Compn. | (wt %) | (mAh/g) | (mAh/g) | cycles) | (mAh/g) | (mAh/g) | (8-106) |
| 1 | LaAlO₃ | 2.6 | 271 | 260 | 97% | 235 | 228 | 97% |
| 2 | La_{2/3}Al_{4/3}O₃ | 1.6 | 276 | 262 | 96% | 244 | 226 | 95% |
| 3 | YAlO₃ | 2.0 | 275 | 262 | 96% | 241 | 227 | 94% |
| Comp. 1 | None | None | 273 | 247 | 94% | 241 | 196 | 83% |
| Comp. 2 | Al₂O₃ | 0.5 | 280 | 259 | 94% | 251 | 223 | 93% |
| Comp. 3 | Al₂O₃ | 1.0 | 278 | 258 | 95% | 248 | 222 | 94% |
| Comp. 4 | La₂O₃ | 1.0 | 273 | 256 | 96% | 237 | 215 | 95% |
| Comp. 5 | La₂O₃ | 2.0 | 271 | 258 | 96% | 232 | 216 | 93% |
| Comp. 6 | La₂O₃ | 3.0 | 271 | 260 | 97% | 229 | 224 | 93% |
| Comp. 7 | AlF₃ | 1.0 | 270 | 253 | 96% | 247 | 225 | 91% |

TABLE 3

| | | | | | | C/10 | | | |
|---|---|---|---|---|---|---|---|---|---|
| | | | | 7^{th} cycle | 107^{th} cycle | Capacity | 8^{th} cycle | 106^{th} cycle | 1 C |
| | | Heating | | C/10 | C/10 | Retention | 1 C | 1 C | Capacity |
| | Coating | Temp. | Coating | Capacity | Capacity | (7-107 | Capacity | Capacity | Retention |
| Example | Compn. | (° C.) | (wt %) | (mAh/g) | (mAh/g) | cycles) | (mAh/g) | (mAh/g) | (8-106) |
| 4 | LaAlO₃ | 150 | 2.6 | 268 | 257 | 96% | 231 | 221 | 96% |
| 5 | LaAlO₃ | 400 | 2.6 | 276 | 266 | 96% | 241 | 235 | 98% |
| 6 | LaAlO₃ | 500 | 2.6 | 272 | 264 | 97% | 237 | 227 | 96% |
| 7 | LaAlO₃ | 750 | 2.6 | 258 | 246 | 95% | 222 | 206 | 93% |
| 8 | LaAlO₃ | 850 | 2.6 | 258 | 249 | 97% | 220 | 206 | 94% |
| 9 | LaAlO₃ | 400 | 1.5 | 268 | 246 | 97% | 226 | 206 | 91% |
| 10 | LaAlO₃ | 400 | 2.6 | 260 | 254 | 98% | 215 | 212 | 99% |
| 11 | LaAlO₃ | 400 | 2.6 | 261 | 253 | 98% | 216 | 211 | 98% |
| Comp. 8 | None | None | None | 279 | 261 | 95% | 240 | 211 | 88% |
| Comp. 9 | AlF₃ | 400 | 1.0 | 274 | 257 | 95% | 253 | 227 | 90% |

TABLE 4

| | | | | | | C/10 | | | |
|---|---|---|---|---|---|---|---|---|---|
| | | | | 7^{th} cycle | 107^{th} cycle | Capacity | 8^{th} cycle | 106^{th} cycle | 1 C |
| | | Heating | | C/10 | C/10 | Retention | 1 C | 1 C | Capacity |
| | Coating | Temp. | Coating | Capacity | Capacity | (7-107 | Capacity | Capacity | Retention |
| Example | Compn. | (° C.) | (wt %) | (mAh/g) | (mAh/g) | cycles) | (mAh/g) | (mAh/g) | (8-106) |
| 12 | LaAlO₃ | 400 | 2.6 | 276 | 264 | 96% | 245 | 234 | 96% |
| 13 | LaAlO₃/AlF₃ | 400 | 1.3/1.0 | 268 | 258 | 96% | 241 | 228 | 95% |
| 14 | LaAlO₃/AlF₃ | 400 | 2.6/1.0 | 275 | 262 | 95% | 249 | 232 | 93% |
| Comp. 10 | None | None | None | 279 | 258 | 92% | 248 | 224 | 90% |
| Comp. 11 | AlF₃ | 400 | 1.0 | 272 | 258 | 95% | 248 | 227 | 92% |

1. A composition useful as a cathode material comprising a lithium metal oxide particulate having a surface at least partially coated with a coating comprised of a complex metal oxide containing aluminum and a second metal that is lanthanum, yttria or combination thereof.

2. The composition of claim 1, wherein the complex metal oxide is amorphous.

3. The composition of claim 1, wherein the molar ratio of the aluminum/second metal is 0.5 to 2.

4. The composition of claim 1, wherein the molar ratio of the aluminum/second metal is essentially 1.

5. The composition of claim 1, wherein the metal of the lithium metal oxide is comprised of Mn, Ni, and Co.

6. The composition of claim 1, wherein the lithium metal oxide is a lithium rich layered metal oxide represented by a formula:
LiₓM_{y}O₂
Where 1<x<2, y is 1 and the metal may be any metal that has an oxidation state from 2 to 4.

7. The composition of claim 1, wherein the lithium metal oxide particulate is comprised of primary particles aggregated into a secondary particle such that the secondary particle has core primary particles that are enveloped by surface primary particles.

8. The composition of claim 7, wherein the coating is unevenly distributed on the surface and core primary particles such that there is more coating on the surface primary particles than the core primary particles.

9. The composition of claim 1, wherein the volume of the coating is 0.2% to 10% by volume of the composition.

10. The composition of claim 1, wherein the coating is comprised of a crystalline structure.

11. The composition of claim 10, wherein the crystalline structure is a perovskite crystalline structure.

12. A method of making a lithium metal oxide coated with a complex metal oxide comprising
(i) providing a lithium metal oxide particulate,
(ii) contacting the lithium metal oxide with a precursor compound that forms a complex metal oxide upon heating, and
(iii) heating to a temperature sufficient to form the complex metal oxide, wherein the complex metal oxide is amorphous and contains aluminum and a second metal that is lanthanum, yttria or combination thereof and the complex metal oxide is bonded to the lithium metal oxide.

13. The method of claim 12, wherein the heating is to a temperature from 350° C. to 450° C.

14. The method of claim 12, wherein the precursor dissolved in a liquid and the liquid is contacted with the lithium metal oxide and the precursor is precipitated onto the surface of the lithium metal oxide.

15. The method of claim 14, wherein at least two precursors are dissolved in the liquid and upon precipitation forms a complex precursor compound having aluminum and a second metal that is lanthanum, yttria or combination thereof.

16. The method of claim 12, wherein the precursor is an aluminum compound that is a nitrate hydrate and at least one yttrium or lanthanum compound that is nitrate hydrate.

17. A lithium ion battery comprising a cathode comprised of the composition of claim 1.

18. The method of claim 14, wherein the lithium metal oxide is first wetted with a liquid not having precursors dissolved therein to form a slurry and then, the liquid having precursors dissolved therein is added to the slurry and the precursor is precipitated onto the lithium metal oxide.

19. The method claim 18, wherein the precipitation is caused by a change in condition of the slurry containing the liquid having precursors dissolved therein.

20. The method of claim 19, wherein the change in condition is a combination of heating and change in pH.
